(19) United States
(12) Patent Application Publication
(10) Pub. No.: US 2010/0285667 A1
(43) Pub. Date: Nov. 11, 2010

(54) METHOD TO PRESERVE THE CRITICAL DIMENSION (CD) OF AN INTERCONNECT STRUCTURE

(75) Inventors: Griselda Bonilla, Fishkill, NY (US); Satyanarayana V. Nitta, Poughquag, NY (US); Terry A. Spooner, Clifton Park, NY (US)

Correspondence Address: SCULLY, SCOTT, MURPHY & PRESSER, P.C., 400 GARDEN CITY PLAZA, SUITE 300, GARDEN CITY, NY, 11530, US

(73) Assignee: International Business Machines Corporation, Armonk, NY (US)

(21) Appl. No.: 12/436,459

(22) Filed: May 6, 2009

(51) Int. Cl. H01L 21/302

(52) U.S. Cl. 438/702; 257/E21.214; 257/E21.295

(57) ABSTRACT

A method of restoring the dielectric constant, loss and leakage of an exposed surface of a low k dielectric material caused during dry etching of the low k dielectric material prior to the removal of the damaged layer by wet etch chemistries is provided. Once restored, the surface of the dielectric material will no longer be susceptible to removal by the highly anisotropic wet etching process. However, the wet etch will still pose an advantage as it can remove any etch/ash residues at the bottom of a feature formed into the low k dielectric material.

### FIELD OF THE INVENTION

The present invention relates to semiconductor technology, and particularly to a method of fabricating an interconnect structure in which the critical dimension (CD) of a feature formed within a low k interconnect dielectric material is preserved That is, the present invention provides a method of fabricating an interconnect structure in which profile blowout and hard mask undercutting is avoided.

### BACKGROUND OF THE INVENTION

Generally, semiconductor devices include a plurality of circuits that form an integrated circuit (IC) fabricated on a semiconductor substrate. A complex network of signal paths will normally be routed to connect the circuit elements distributed on the surface of the substrate. Efficient routing of these signals across the device requires formation of multilevel or multilayered schemes, such as, for example, single or dual damascene wiring structures. The wiring structure typically includes copper (Cu) since Cu-based interconnects provide higher speed signal transmission between large numbers of transistors on a complex semiconductor chip as compared with aluminum, e.g., Al,-based interconnects.

Within a typical interconnect structure, metal vias run perpendicular to the semiconductor substrate and metal lines run parallel to the semiconductor substrate. Further enhancement of the signal speed and reduction of signals in adjacent metal lines (known as “crosstalk”) are achieved in today's IC product chips by embedding the metal lines and metal vias (e.g., conductive features) in a dielectric material (either porous or non-porous) having a dielectric constant of less than 4.0. Dielectric materials having a dielectric constant of less than 4.0 are referred to herein as low k dielectric materials.

Generally, low k dielectric materials, which are typically used as the interconnect dielectric material, are susceptible to damage during back-end-of-the-line (BEOL) dry etching processes. This damage is typically characterized as a carbon gradient through the film where the carbon concentration is lower near the etched surface of the low k dielectric material gradually increasing throughout the bulk of the low k dielectric material. This affects the integrity of the low k dielectric as an interconnect dielectric material, causing a degradation of the dielectric constant as well as loss and leakage of the dielectric film. The presence of this damaged dielectric layer can lead to reliability failure and it is best to try to decrease the amount of damage of the low k dielectric material, remove this damage, and/or repair the damage layer.

Removal of the damaged layer with fluorine-based wet chemistries can lead to loss of profile control due to the fact that the damaged layer is non-uniform (i.e., more damage occurs at the etched dielectric surface). Moreover, since the wet etch is anisotropic, the profile of the etched feature will no longer be straight and lead to undercutting of the low k dielectric material beneath the hard mask which is located on the upper surface of the low k dielectric material.

### SUMMARY OF THE INVENTION

A method of repairing a damaged layer formed within a low k interconnect dielectric material by dry etching prior to damage removal is provided. Such a method protects the etched sidewall surfaces and trench bottom surfaces of the low k dielectric material from profile blowout and hard mask undercut.

Specifically, the invention provides a method of restoring the dielectric constant, loss and leakage of an exposed etched surface of a low k dielectric material caused during dry etching of the low k dielectric material prior to the removal of the damaged layer by wet etch chemistries. Once restored, the surface of the dielectric material will no longer be susceptible to removal by the highly anisotropic wet etching process. However, the wet etch will still pose an advantage as it can remove any etch/ash residues at the bottom of the etched feature formed into the low k dielectric material.

The inventive method provides tighter profile control, and hence, better metal barrier coverage for all low k dielectric interconnect levels and across all features of the interconnect structure.

In addition, the restoration of the damaged layer will decrease the overall effective dielectric constant and the leakage of the interconnect structure, which will render the interconnect structure more reliable than prior art interconnect structures.

In one aspect of the invention, a method of fabricating an interconnect structure is provided that includes:

providing an initial interconnect structure including a lower interconnect level and an upper interconnect level that are separated by a dielectric capping layer, wherein the lower interconnect level includes a first dielectric material having at least one conductive feature embedded therein and the second interconnect level includes a second dielectric material that is capped with a hard mask;
forming at least one opening within the hard mask, the second dielectric material and the dielectric capping layer, wherein exposed surfaces of the second dielectric material within the at least one opening are damaged forming a damaged layer having properties that differ from the remaining portions of the second dielectric material;
restoring the properties of the damaged layer to that of the second dielectric material; removing residue from a bottom portion of the at least one opening utilizing a wet cleaning process; and
forming a diffusion barrier and a conductive material within said at least one opening.

### BRIEF DESCRIPTION OF THE DRAWINGS

FIG. 1 is a pictorial representation (through a cross sectional view) illustrating an initial interconnect structure that can be employed in the present application.

FIG. 2 is a pictorial representation (through a cross sectional view) illustrating the structure of FIG. 1 after forming at least one opening within the interconnect structure.

FIG. 3 is a pictorial representation (through a cross sectional view) illustrating the structure of FIG. 2 after removing a damaged layer from the interconnect structure.

FIG. 4 is a pictorial representation (through a cross sectional view) illustrating the structure of FIG. 3 after forming a diffusion barrier and a conductive material within the at least one opening of the interconnect structure.

FIG. 5 is a pictorial representation (through a cross sectional view) illustrating a prior art interconnect structure in which profile blowout and hard mask undercutting is observed.

### DETAILED DESCRIPTION OF THE INVENTION

The present invention, which provides a method of fabricating an interconnect structure have a tighter profile control, will now be described in greater detail by referring to the following discussion and drawings that accompany the present application. It is noted that the drawings of the present application are provided for illustrative purposes only and, as such, the drawings are not drawn to scale.

In the following description, numerous specific details are set forth, such as particular structures, components, materials, dimensions, processing steps and techniques, in order to provide a thorough understanding of the present invention. However, it will be appreciated by one of ordinary skill in the art that the invention may be practiced without these specific details. In other instances, well-known structures or processing steps have not been described in detail in order to avoid obscuring the invention.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Reference is now made to FIGS. 1-4 which illustrate the basic processing steps that are employed in the present invention. Specifically, FIG. 1 illustrates an initial interconnect structure 10 that can be used in the present invention. The initial interconnect structure 10 shown in FIG. 1 includes a multilevel interconnect structure including a lower interconnect level 12 and an upper interconnect level 16 that are separated by a dielectric capping layer 14. The lower interconnect level 12, which may be located above a semiconductor substrate (not shown) including one or more semiconductor devices (also not shown), includes a first dielectric material 18 having at least one conductive feature (i.e., a conductive region) 20 that is separated from the first dielectric layer 18 by a barrier layer (not shown). The upper interconnect level 16 comprises a second dielectric material 24. A hard mask 26 is located atop the upper exposed surface of the second dielectric material 24.

The initial structure 10 shown in FIG. 1 is made utilizing conventional techniques well known to those skilled in the art. For example, the initial interconnect structure 10 can be formed by first applying the first dielectric material 18 to a surface of a substrate (not shown). The substrate, which is not shown, may comprise a semiconducting material, an insulating material, a conductive material or any combination thereof. When the substrate is comprised of a semiconducting material, any semiconductor such as Si, SiGe, SiGeC, SiC, Ge alloys, GaAs, InAs, InP and other III/V or II/VI compound semiconductors may be used. In addition to these types of semiconducting materials, the present invention also contemplates cases in which the semiconductor substrate is a layered semiconductor such as, for example, Si/SiGe, Si/SiC, silicon-on-insulators (SOIs) or silicon germanium-on-insulators (SGOIs).

When the substrate is an insulating material, the insulating material can be an organic insulator, an inorganic insulator or a combination thereof including multilayers. When the substrate is a conducting material, the substrate may include, for example, polySi, an elemental metal, alloys of elemental metals, a metal silicide, a metal nitride or combinations thereof including multilayers. When the substrate comprises a semiconducting material, one or more semiconductor devices such as, for example, complementary metal oxide semiconductor (CMOS) devices can be fabricated thereon.

The first dielectric material 18 of the lower interconnect level 12 may comprise any interlevel or intralevel dielectric having a dielectric constant of less than 4.0 (e.g., less than the dielectric constant of silicon dioxide). The first dielectric material 18 may include inorganic dielectrics or organic dielectrics. The first dielectric material 18 may be porous or non-porous, with porous dielectrics having a dielectric constant of about 2.8 or less being highly preferred in some embodiments of the present invention. Some examples of suitable dielectrics that can be used as the first dielectric material 18 include, but are not limited to silsesquioxanes, C doped oxides (i.e., organosilicates) that include atoms of Si, C, O and H, thermosetting polyarylene ethers, or multilayers thereof. The term “polyarylene” is used in this application to denote aryl moieties or inertly substituted aryl moieties which are linked together by bonds, fused rings, or inert linking groups such as, for example, oxygen, sulfur, sulfone, sulfoxide, carbonyl and the like.

The first dielectric material 18 typically has a dielectric constant that is less than 4.0, with a dielectric constant of about 2.4 or less being even more typical. These dielectrics generally have a lower parasitic crosstalk as compared with dielectric materials that have a higher dielectric constant. The thickness of the first dielectric material 18 may vary depending upon the dielectric material used as well as the exact number of dielectrics within the lower interconnect level 12. Typically, and for normal interconnect structures, the first dielectric material 18 has a thickness from 200 nm to 450 nm.

The lower interconnect level 12 also has at least one conductive feature 20 that is embedded in (i.e., located within) the first dielectric material 18. The conductive feature 20 comprises a conductive material that is separated from the first dielectric material 18 by a barrier layer (not shown). The conductive feature 20 is formed by lithography (i.e., applying a photoresist to the surface of the first dielectric material 18, exposing the photoresist to a desired pattern of radiation, and developing the exposed resist utilizing a conventional resist developer), etching (dry etching or wet etching) an opening in the first dielectric material 18 and filling the etched region with the barrier layer and then with a conductive material forming the conductive region. The barrier layer, which may comprise Ta, TaN, Ti, TiN, Ru, RuN, W, WN or any other material that can serve as a barrier to prevent conductive material from diffusing there through, is formed by a deposition process such as, for example, atomic layer deposition (ALD), chemical vapor deposition (CVD), plasma enhanced chemical vapor deposition (PECVD), physical vapor deposition (PVD), sputtering, chemical solution deposition, or plating.

The thickness of the barrier layer may vary depending on the exact means of the deposition process as well as the material employed. Typically, the barrier layer has a thickness from 4 nm to 40 nm, with a thickness from 7 nm to 20 nm being more typical.

Following the barrier layer formation, the remaining region of the opening within the first dielectric material 18 is filled with a conductive material forming the conductive feature 20. The conductive material used in forming the conductive feature 20 includes, for example, polySi, a conductive metal, an alloy comprising at least one conductive metal, a conductive metal silicide or combinations thereof. Preferably, the conductive material that is used in forming the conductive feature 20 is a conductive metal such as Cu, W or Al, with Cu or a Cu alloy (such as AlCu) being highly preferred in the present invention. The conductive material is filled into the remaining opening in the first dielectric material 18 utilizing a conventional deposition process including, but not limited to CVD, PECVD, sputtering, chemical solution deposition or plating.

After deposition, a conventional planarization process such as, for example, chemical mechanical polishing (CMP) can be used to provide a structure in which the barrier layer (which is now U-shaped) and the conductive feature 20 each have an upper surface that is substantially coplanar with the upper surface of the first dielectric material 18.

After forming the at least one conductive feature 20, a blanket dielectric capping layer 14 is formed on the surface of the lower interconnect level 12 utilizing a conventional deposition process such as, for example, CVD, PECVD, chemical solution deposition, or evaporation. The dielectric capping layer 14 comprises any suitable dielectric capping material such as, for example, SiC, Si₄NH₃, SiO₂, a carbon doped oxide, a nitrogen and hydrogen doped silicon carbide SiC(N,H) or multilayers thereof. The thickness of the capping layer 14 may vary depending on the technique used to form the same as well as the material make-up of the layer Typically, the dielectric capping layer 14 has a thickness from 15 nm to 55 nm, with a thickness from 25 nm to 45 nm being more typical.

Next, the upper interconnect level 16 is formed by applying the second dielectric material 24 to the upper exposed surface of the dielectric capping layer 14. The second dielectric material 24 may comprise the same or different, preferably the same, dielectric material as that of the first dielectric material 18 of the lower interconnect level 12. The processing techniques and thickness ranges for the first dielectric material 18 are also applicable here for the second dielectric material 24. The second dielectric material 24 can also comprise two different materials, i.e., deposition of one dielectric material first, followed by deposition of a different dielectric material. In one embodiment of the present invention, the second dielectric material 24 comprises two different low k dielectric materials and thus the upper interconnect level 16 has a hybrid structure with the subsequently filled conductively filled line embedded in a porous dielectric material, and the subsequently filled via embedded in a dense (i.e., non porous) dielectric material. In such an embodiment, the porous low k dielectric has a dielectric constant of about 2.8 or less, and the dense porous low k dielectric has a dielectric constant of less than 4.0.

After forming the second dielectric material 24, a hard mask 26 is formed on an exposed upper surface of the second dielectric material 24. The hard mask 26 includes an oxide, nitride, oxynitride or any combination including multilayers thereof. Typically, the hard mask 26 is an oxide such as SiO₂ or a nitride such as Si₃N₄. The hard mask 26 is formed utilizing a conventional deposition process such as, for example, CVD, PECVD, chemical solution deposition or evaporation. The thickness of the as-deposited hard mask 26 may vary depending upon the type of hard mask material formed, the number of layers that make up the hard mask and the deposition technique used in forming the same. Typically, the as-deposited hard mask 26 has a thickness from 10 nm to 80 nm, with a thickness from 20 nm to 60 nm being even more typical.

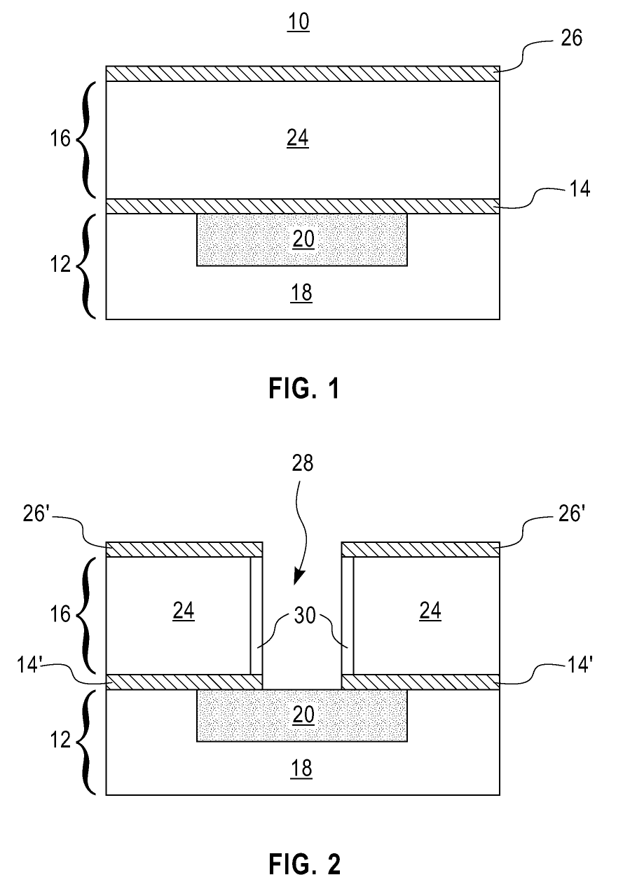

Next, and as shown in FIG. 2, at least one opening 28 is formed into the second dielectric material 24 and the hard mask 26. The at least one opening 28 may be a via opening (as shown), a line opening (not shown) or a combination of a via opening and a line opening (also not shown), in which the line opening is located atop, and connect to, the via opening. The at least one opening 28 is formed by conventional lithography and etching. When a combined via opening and line opening are present, a conventional dual damascene can be used. In some cases, the dual damascene process may include formation of a via followed by formation of a line. In other embodiments, the line is formed prior to forming the via.

Specifically, the at least one opening 28 is formed by applying a photoresist (not shown) atop the hard mask 26 shown in FIG. 1 utilizing a conventional deposition process such as, for example, CVD, PECVD, spin-on coating, chemical solution deposition or evaporation. The photoresist may be a positive-tone material, a negative-tone material or a hybrid material, each of which is well known to those skilled in the art. The photoresist is then subjected to a lithographic process which includes exposing the photoresist to a pattern of radiation (either a via pattern or a line pattern) and developing the exposed resist utilizing a conventional resist developer. The lithographic step provides a patterned photoresist atop the hard mask 26 that defines the width of the opening 28.

After providing the patterned photoresist, the pattern (e.g., via or line) is transferred into the hard mask 26 and then subsequently into the second dielectric material 24 utilizing one or more etching process. The patterned photoresist can be stripped immediately after the pattern is transferred into the hard mask forming patterned hard mask 26′ utilizing a conventional stripping process. Alternatively, the patterned photoresist can be stripping after the pattern is transferred into the second dielectric material 24. The etching used in transferring the pattern may comprise a dry etching process such as reactive-ion etching, ion beam etching, plasma etching or laser ablation. In a dual damascene process, another iteration of lithography and etching is performed.

It is observed that during the dry etching process that is used to form the at least one opening 28 into the second dielectric material 24, the dielectric capping layer 14 is opened forming patterned dielectric capping layer 14′.

It is also observed that during the dry etching process used to form the at least one opening 28 the etched and now exposed surfaces (including sidewalls and bottom walls, e.g., trench walls) are damaged providing damaged layer 30. The damaged layer 30, which is located at a now exposed surface of the second dielectric material 24, typically has a lower concentration of C as compared to the remaining portion of the second dielectric material 24. When C is not present in the dielectric material, the damaged layer tends to be more porous than the remaining portion of the second dielectric material. It is farther observed that the damaged layer 30 has different properties than the remaining undamaged portion of the second dielectric material 24. The different properties include one of hydrophobicity, elastic modulus, low dielectric constant, feature toughness and hardness.

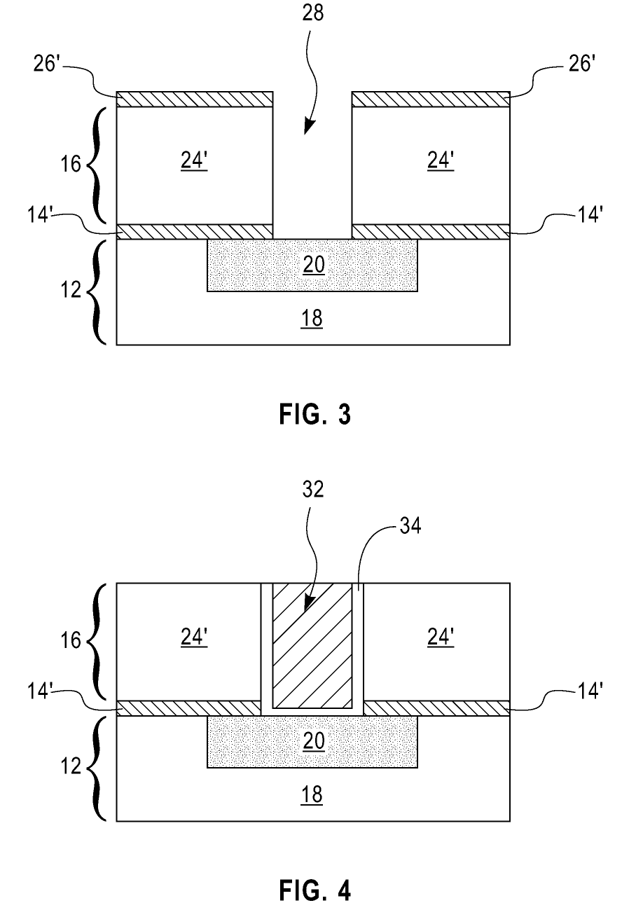

At this point of the present invention, the damaged layer 30 is repaired providing the structure shown in FIG. 3. The repaired dielectric material is labeled as 24′ in FIG. 3. The properties that are restored by the method of the invention include one of hydrophobicity, elastic modulus, low dielectric constant, feature toughness and hardness.

Specifically, the damaged layer 30 is repaired by treating the same with a silylating agent which is capable of converting the pendant silanol groups on the damaged surface of the dielectric material to a different functional group resulting in a recovery (i.e., restoration) of the hydrophobicity of the damaged dielectric material and reduction of the dielectric constant from its damaged state.

In one embodiment of the invention, the silylating agent comprises an aminosilane, so as to render the film hydrophobic. The aminosilane may have the general formula (R₂N)_{X}SiR′_{Y} where X and Y are integers from 1 to 2 and 2 to 1, respectively, and where R and R′ are selected from the group consisting of hydrogen, alkyl, aryl, allyl, phenyl and a vinyl moiety. Preferably, the aminosilane is bis(dimethylamino)dimethylsilane.

The aminosilane may also have the general formula (R₂N)_{X}SiR_{Y}R″_{Z} where X, Y and Z are integers from 1 to 3, 3 to 1 and 1 to 3, respectively, and where R, R′, and R″ are any hydrogen, alkyl, or aryl, allyl, phenyl or vinyl moiety.

In other embodiments, the silylating agent has the formula R_{X}H_{Y}Si-A where X and Y are integers from 0 to 2 and 3 to 1, respectively, and where R, is any hydrogen, alkyl, or aryl, allyl, phenyl or vinyl moiety and where A is a silazane, chloro, amino or alkoxy moiety. The silylating agent may comprise amino, chloro and alkoxy terminated monofunctional terminated silylating agent, wherein methyl moieties on the silylating agent are at least partially replaced by hydrogen analogues. The silylating agent may also comprise a polymeric siloxane with amino, alkoxy, chloro or silazane terminated end groups. The end groups of the polymeric siloxanes may comprise mono or di alkyl, aryl, vinyl or hydrogen moieties. The siloxane may comprise amino terminated polydimethylsiloxane.

The silylating agent also may have the general formula R_{X}H_{Y}Si_{Z}A where X, and Y, are integers from 0 to 5, and 6 to 1, respectively, and Z is equal to, 1 to 2 and where R is a hydrogen, alkyl, aryl, allyl, phenyl or vinyl moiety, and A is a silazane, chloro, amino or alkoxy moiety.

Examples of preferred silylating agents that can be employed in the present invention include, but are not limited to hexamethyldisilazane, bis(dimethylamino)dimethylsilane, or (dimethylamino)trimethylsilane. Of these silylating agents, it is highly preferred to use bis(dimethylamino)dimethylsilane as the silylating agent.

The silylating agent may be applied by one of spin coating a liquid, immersing the structure in a liquid, spray coating the structure with a liquid, in a vapor phase, or dissolved in super critical carbon dioxide, preferably with a co-solvent selected from at least one of alkanes, alkenes, ketones, ethers, and esters. The silylating agent is generally applied in an absence of moisture.

The structure including the damaged dielectric layer may be annealed, preferably at a temperature of at least 350° C., or as high as 450° C. for a period in excess of one minute. The annealing may be performed before or after applying the silylating agent. The silylating agent is preferably applied at a temperature of at least 25° C.

The silylating agent may be dissolved in a solvent, including a non-polar organic solvent with low surface tension selected from the group comprising alkanes, alkenes, ketones, ethers, esters, or any combinations thereof. Preferably, the solvent has a low enough surface tension so as to penetrate pores in the film. The silylating agent may preferably have a concentration from 2 percent to 10 percent by weight in the solvent, but may also have a concentration of as low as one half percent or greater by weight in the solvent.

The silylating agent may be applied for a period of time between one minute and one hour, at room temperature or higher. Agitation or ultrasonification may be utilized when the silylating agent is applied. The silylated treated structure may be rinsed to remove excess silylating agent. Additionally, the silylated treated structure may be baked, preferably at a temperature of up to 450° C.

The silylating agent may be applied in a vapor phase, at temperatures between room temperature (typically from 15° C. to 30° C.) and 450° C. for a duration of thirty seconds to one hour, or substantially 250° C., for a duration of five minutes. The silylating agent may be applied in super critical carbon dioxide, at temperatures between 25° C. and 450° C., at a pressure between 1000 and 10,000 psi, for a duration of thirty seconds to one hour. It may also be applied in super critical carbon dioxide or vapor media at temperature in excess of 75° C. for times in excess of 30 seconds.

Next, a wet chemical cleaning process is used to remove any etch and/or ash residue from the bottom of the at least one opening 28. The residues are typically comprised of a complex mixture that may include re-sputtered oxide material and small amounts of organic material from the resists used to form the openings. The composition of these residues is highly dependent on the etch gas chemistries and the materials present during the etch, but typically these are dissolved in a mixture of aqueous and/or organic solutions with fluorine containing compounds. Typically, dilute hydrofluoric acid is used to remove the etch and/or ash residue from the structure.

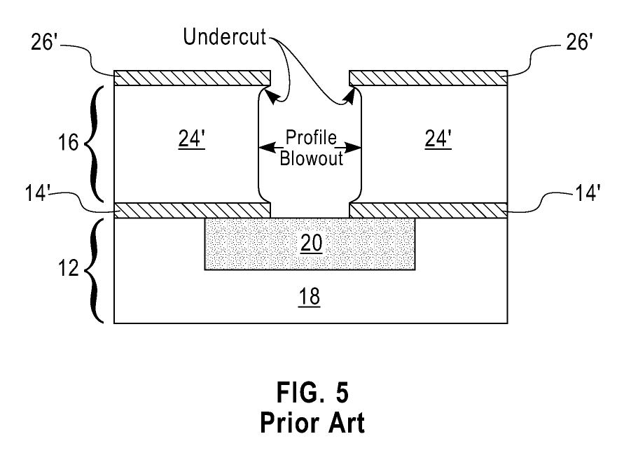

It is noted that by performing the restoration treatment prior to the cleaning step the critical dimension and/or profile of the at least one opening is maintained (e.g., the profiles have substantially straight walls) with no angle or taper in the final profile shape. Note that the profile is maintained along all interfaces of the different materials present in the structure. FIG. 5 shows a prior art interconnect structure in which the damaged layer is removed by a fluorine-based etchant. In this drawing, the reference numerals used correspond to like elements that are shown in, and referenced to within, FIG. 2. It is observed that profile control is not maintained (evident by the profile not containing straight wall portions) in the prior art structure. It is well known that selective fluorine based etchants will remove oxide-based materials at 100-500 times greater rate compared to metal, silicon, silicide and/or interlevel dielectric materials that might also be exposed to the cleaning composition. Since the damage material (30 in FIG. 2) is oxide-like (depleted of C due to the plasma interaction with the pristine dielectric), it will also etch at a faster rate than that of the hardmask layer (26′ in FIG. 2) or that of the barrier material (14′ in FIG. 2). This causes a distortion in the shape such that the opening will have a taper less than the desired 90 degrees. Additionally, at the hardmask/dielectric interface and/or the barrier/dielectric interface, the dielectric is recessed. The degree of the recess depends on the extent of the damage caused by the etch process to the dielectric material (24′).

It is also noted that the resistivity values of structures that are subjected to silylation prior to DHF cleaning are higher (approximately 5%) than interconnect structures that are silylated after DHF cleaning.

Next, and as shown in FIG. 4, a diffusion barrier 34 and a conductive material 32 are formed into each of the at least one openings 28. The diffusion barrier 34 comprises Ta, TaN, Ti, TiN, Ru, RuN, RuTa, RuTaN, IrTa, IrTaN, W, VN or any other material that can serve as a barrier to prevent conductive material from diffusing there through. The thickness of the diffusion barrier 34 may vary depending on the deposition process used as well as the material employed. Typically, the diffusion barrier 34 has a thickness from 4 nm to 40 nm, with a thickness from 7 nm to 20 nm being more typical.

The diffusion barrier 34, which is located between the conductive material 32 and the restored second dielectric material 24′ is formed by any conventional deposition process including, for example, atomic layer deposition (ALD), plasma enhanced atomic layer deposition (PEALD), CVD, PECVD, PVD, sputtering and plating. In some embodiments, the diffusion barrier 34 is removed from a bottom portion of the least one opening prior to filling the same with a conductive material.

In some embodiments, a plating seed layer (not shown) is formed atop the diffusion barrier 34 prior to forming the conductive material 32. When present, the plating seed layer includes a Ru-containing material, an Ir-containing material or mixtures thereof. For example, the plating seed layer may comprise Ru, a combination of TaN and Ru, a combination of TiSiN and Ru, Ir, a combination of TaN and Ir, a combination of TiSiN and Ir. Preferably, the plating seeding layer comprises Ru or Ir, with Ru being highly preferred.

The plating seed layer is formed utilizing a conventional deposition process such as, for example, ALD, CVD, PECVD, chemical solution deposition and other like deposition process in which a Ru-containing precursor and/or an Ir-containing precursor are used in the deposition of the plating seed layer.

The conductive material 32, which may be the same or different from the conductive material within the lower interconnect level, includes, for example, polySi, a conductive metal, an alloy comprising at least one conductive metal, a conductive metal silicide or combinations thereof. Preferably, the conductive material 32 that is used in forming the conductive region is a conductive metal such as Cu, W or Al, with Cu or a Cu alloy (such as AlCu) being highly preferred in the present invention.

The conductive material 32 is formed into each of the openings 28 that are lined with the diffusion barrier 34 utilizing any conventional deposition process including, for example, CVD, PECVD, PVD, sputtering, plating, chemical solution deposition and electroless plating. After deposition of the conductive material 32, the structure is subjected to a planarization process such as, for example, chemical mechanical polishing (CMP) and/or grinding. The planarization process provides a planar structure such as is shown in FIG. 4 in which the upper surfaces of the second dielectric material 24′, the diffusion barrier 34 and the conductive material 32 are substantially coplanar with each other. It is observed that during the planarization process, the patterned hard mask is removed from the structure.

The above processing steps may be repeated in forming a multilayered interconnect structure having the tight profile control mentioned above.

It is observed that in the drawings described above, the at least one opening is aligned to the surface of the underlying conductive material of the first interconnect level. In some embodiments, the at least one opening can be mis-aligned. In such cases, an additional repair treatment, as described above, can be performed to prevent etching out of the first dielectric material.

It is further observed that the present invention can also be used when a gouging feature is formed into the conductive feature of the lower interconnect level via a sputtering process, such as Ar sputtering. In such an instance, the treatment with the silylating agent may be performed before and/or after the gouging feature is formed into the conductive feature of the lower interconnect level.

While the present invention has been particularly shown and described with respect to preferred embodiments thereof, it will be understood by those skilled in the art that the foregoing and other changes in forms and details may be made without departing from the spirit and scope of the present invention. It is therefore intended that the present invention not be limited to the exact forms and details described and illustrated, but fall within the scope of the appended claims.

What is claimed is:

1. A method of fabricating an interconnect structure comprising:
providing an initial interconnect structure including a lower interconnect level and an upper interconnect level that are separated by a dielectric capping layer, wherein the lower interconnect level includes a first dielectric material having at least one conductive feature embedded therein and the second interconnect level includes a second dielectric material that is capped with a hard mask;
forming at least one opening within the hard mask, the second dielectric material and the dielectric capping layer, wherein exposed surfaces of the second dielectric material within the at least one opening are damaged forming a damaged layer having properties that differ from the remaining portions of the second dielectric material;
restoring the properties of the damaged layer to that of the second dielectric material;
removing residue from a bottom portion of the at least one opening utilizing a wet cleaning process; and
forming a diffusion barrier and a conductive material within said at least one opening.

2. The method of claim 1 wherein said at least one opening is a via opening, a line opening, a combination of a via opening and a line opening, or any combination thereof.

3. The method of claim 1 wherein said forming the at least one opening includes a dry etching process.

4. The method of claim 1 wherein said restoring the properties of the damaged layer comprises treating the damaged layer with a silylating agent.

5. The method of claim 4 wherein the silylating agent comprises a compound having the formula (R₂N)_{X}SiR′_{Y} where X and Y are integers from 1 to 2 and 2 to 1, respectively, and where R and R′ are selected from the group consisting of hydrogen, alkyl, aryl, allyl, phenyl and a vinyl moiety.

6. The method of claim 4 wherein the silylating agent comprises a compound having the formula (R₂N)ₓSiR_{Y}R″_{Z} where X, Y and Z are integers from 1 to 3, 3 to 1, and 1 to 3, respectively, and where R, R′, and R″ are any hydrogen, alkyl, or aryl, allyl, phenyl or vinyl moiety.

7. The method of claim 4 wherein the silylating agent comprises a compound having the formula R_{X}H_{Y}Si-A where X and Y are integers from 0 to 2 and 3 to 1, respectively, and where R, is any hydrogen, alkyl, or aryl, allyl, phenyl or vinyl moiety and where A is a silazane, chloro, amino or alkoxy moiety.

8. The method of claim 4 wherein the silylating agent comprises a compound having the formula R_{X}H_{Y}Si_{Z}A where X, and Y, are integers from 0 to 5, and 6 to 1, respectively, and Z is equal to, 1 to 2 and where R is a hydrogen, alkyl, aryl, allyl, phenyl or vinyl moiety, and A is a silazane, chloro, amino or alkoxy moiety.

9. The method of claim 4 wherein said silylating agent is applied by one of spin coating a liquid, immersing in a liquid, spray coating with a liquid, in a vapor phase, and dissolved in super critical carbon dioxide.

10. The method of claim 1 wherein said removing the residue includes contacting by dilute hydrofluoric acid.

11. A method of fabricating an interconnect structure comprising:
providing an initial interconnect structure including a lower interconnect level and an upper interconnect level that are separated by a dielectric capping layer, wherein the lower interconnect level includes a first dielectric material having at least one conductive feature embedded therein and the second interconnect level includes a second dielectric material that is capped with a hard mask;
forming at least one opening within the hard mask, the second dielectric material and the dielectric capping layer, wherein exposed surfaces of the second dielectric material within the at least one opening are damaged forming a damaged layer having properties that differ from the remaining portions of the second dielectric material;
treating the damaged layer with a silylating agent to restore properties of the damaged layer to that of the second dielectric material;
removing residue from a bottom portion of the at least one opening utilizing a wet cleaning process; and
forming a diffusion barrier and a conductive material within said at least one opening.

12. The method of claim 11 wherein said at least one opening is a via opening, a line opening, a combination of a via opening and a line opening, or any combination thereof.

13. The method of claim 11 wherein said forming the at least one opening includes a dry etching process.

14. The method of claim 11 wherein the silylating agent comprises a compound having the formula (R₂N)_{X}SiR′_{Y} where X and Y are integers from 1 to 2 and 2 to 1, respectively, and where R and R′ are selected from the group consisting of hydrogen, alkyl, aryl, allyl, phenyl and a vinyl moiety.

15. The method of claim 11 wherein the silylating agent comprises a compound having the formula (R₂N)ₓSiR_{Y}R″_{Z} where X, Y and Z are integers from 1 to 3, 3 to 1, and 1 to 3 respectively, and where R, R′, and R″ are any hydrogen, alkyl, or aryl, allyl, phenyl or vinyl moiety.

16. The method of claim 11 wherein the silylating agent comprises a compound having the formula R_{X}H_{Y}Si-A where X and Y are integers from 0 to 2 and 3 to 1, respectively, and where R, is any hydrogen, alkyl, or aryl, allyl, phenyl or vinyl moiety and where A is a silazane, chloro, amino or alkoxy moiety.

17. The method of claim 11 wherein the silylating agent comprises a compound having the formula R_{X}H_{Y}Si_{Z}A where X, and Y, are integers from 0 to 5, and 6 to 1, respectively, and Z is equal to, 1 to 2 and where R is a hydrogen, alkyl, aryl, allyl, phenyl or vinyl moiety, and A is a silazane, chloro, amino or alkoxy moiety.

18. The method of claim 11 wherein said silylating agent is applied by one of spin coating a liquid, immersing in a liquid, spray coating with a liquid, in a vapor phase, and dissolved in super critical carbon dioxide.

19. The method of claim 11 wherein said removing the residue includes contacting by dilute hydrofluoric acid.

20. A method of fabricating an interconnect structure comprising:
providing an initial interconnect structure including a lower interconnect level and an upper interconnect level that are separated by a dielectric capping layer, wherein the lower interconnect level includes a first dielectric material having at least one conductive feature embedded therein and the second interconnect level includes a second dielectric material that is capped with a hard mask;
forming at least one opening within the hard mask, the second dielectric material and the dielectric capping layer, wherein exposed surfaces of the second dielectric material within the at least one opening are damaged forming a damaged layer having a lower C concentration than that present in the remaining portions of the second dielectric material;
treating the damaged layer with a silylating agent;
removing residue from a bottom portion of the at least one opening utilizing a wet cleaning process; and
forming a diffusion barrier and a conductive material within said at least one opening.

21. The method of claim 20 wherein the silylating agent comprises a compound having the formula (R₂N)_{X}SiR′_{Y} where X and Y are integers from 1 to 2 and 2 to 1 respectively, and where R and R′ are selected from the group consisting of hydrogen, alkyl, aryl, allyl, phenyl and a vinyl moiety.

22. The method of claim 20 wherein the silylating agent comprises a compound having the formula (R₂N)_{X}SiR_{Y}R″_{Z} where X, Y and Z are integers from 1 to 3, 3 to 1, and 1 to 3, respectively, and where R, R′, and R″ are any hydrogen, alkyl, or aryl, allyl, phenyl or vinyl moiety.

23. The method of claim 20 wherein the silylating agent comprises a compound having the formula R_{X}H_{Y}Si-A where X and Y are integers from 0 to 2 and 3 to 1, respectively, and where R, is any hydrogen, alkyl, or aryl, allyl, phenyl or vinyl moiety and where A is a silazane, chloro, amino or alkoxy moiety.

24. The method of claim 20 wherein the silylating agent comprises a compound having the formula R_{X}H_{Y}Si_{Z}A where X, and Y, are integers from 0 to 5, and 6 to 1, respectively, and Z is equal to, 1 to 2 and where R is a hydrogen, alkyl, aryl, allyl, phenyl or vinyl moiety, and A is a silazane, chloro, amino or alkoxy moiety.

25. The method of claim 20 wherein said silylating agent is applied by one of spin coating a liquid, immersing in a liquid, spray coating with a liquid, in a vapor phase, and dissolved in super critical carbon dioxide.
